(19) United States
(12) Patent Application Publication
(10) Pub. No.: US 2013/0170163 A1
(43) Pub. Date: Jul. 4, 2013

(54) ELECTRICAL COMPONENT WHICH CAN BE RELIABLY SOLDERED

(71) Applicant: Abdallah Fakhri, Volsins Le'Bretonneux (FR)

(72) Inventor: Abdallah Fakhri, Volsins Le'Bretonneux (FR)

(73) Assignee: J.S.T. MFG. CO., LTD., Osaka-shi, Osaka (JP)

(21) Appl. No.: 13/808,147

(22) PCT Filed: Jul. 6, 2010
(86) PCT No.: PCT/IB2010/002048

§ 371 Date: Mar. 21, 2013

(51) Int. Cl. H05K 1/18

(52) U.S. Cl. CPC H05K 1/181
USPC 361/760

(57) ABSTRACT

Electrical component (10), comprising at least one pin (14) provided to be soldered on a PCB surface (60) using Surface Mount Technology (SMT). A mobile part (36) is movably mounted on the pin.

The mobile part is adapted, when the component is brought next to said surface in order to be fastened and soldered thereon, to abut against said surface and to move with respect to said pin, so as to adopt a position wherein it bridges a gap (D) between the pin and the surface to allow soldering of the pin on the surface. Accordingly, even if the surface is warped, or the solder end portion the pin is not positioned in the desired location, a reliable soldering of the pin can be achieved.

The present invention concerns the assembling of electrical components on the surface of boards (in particular, PCBs or printed circuit boards) by soldering. In particular, it concerns the mounting of such components using Surface Mounting Technology (SMT), wherein the pins of the components are soldered on the surface of a board without being nailed or fastened through the board.

Solder joint reliability is always a concern to the manufacturer.

In this respect, and especially for electrical components comprising a large numbers of pins, two causes of soldering problems have been identified:
a deformation or warping of the board may take place; and/or
the solder ends of the pins may not be sufficiently coplanar.

In both cases, the end of the pins, instead of abutting gently on the board or PCB, where they are to be soldered, may either collide with the board, which eventually will not hinder soldering, but can create strains which over time can lead to breaks in the joints; or, some of the pins may be too far away from the board, whereby soldering of the pins does not take place or is defective.

A solution to avoid such problems is presented by Japanese patent application Nr 09-306571 (JP1997-306571). This document presents a component with a plurality of connection pins which are to be soldered on a planar surface. The end portion (or solder portion) of each of the pins is overmoulded with a metal sleeve. These sleeves are moulded so as to make sure that the bottom portions of all the sleeves are positioned in the same plane, thus preventing any misalignment problem of the pins. If needed, the sleeves may also be pressed or cut so as to match the level of the surface.

However, this solution requires moulding of sleeves on solder ends of the pins. It is thus time-consuming and costly. Moreover, it does not solve the problem arising if the board itself is warped or deformed.

Accordingly, it is a purpose of the present invention to provide an electrical component, with at least one connection pin, which can be reliably soldered on the surface of a PCB using Surface Mount Technology (SMT) despite variations either in height of the surface of the board due to PCB warping, or of the height of the pin(s) (non-coplanarity of pins), in a soldering direction. The soldering direction is here the direction perpendicular to the surface of the board, on which the component is to be fastened and soldered.

In accordance with the present invention, an electrical component is provided, which comprises at least one pin to be soldered on a surface; wherein a mobile part is movably mounted on the pin, and wherein the mobile part is adapted, when the component is brought next to said surface in order to be soldered thereon, to abut against said surface and to move with respect to said pin, so as to adopt a position wherein it bridges a gap between the pin and the surface to allow soldering of the pin on the surface.

Of course, the point of the surface on which the pin is soldered is normally a part of the surface where an electric circuit passes. Therefore, the soldering of the pin on the surface (at this point) creates a desired electric contact between the circuit and the pin.

Preferably, the mobile part protrudes ahead of the pin a soldering direction, at least at the beginning of the soldering operation, when the component is brought next to the surface to be placed in its desired position.

When the component is brought next to the surface, the mobile part abuts against the surface. It is then pushed back by the surface (away from the soldering direction) and moves relative to the pin, until it takes a final, soldering position during reflow soldering.

During this movement, the mobile part moves or retracts somewhat to allow the component to reach its final position. Whatever the relative position of the pin with respect to the board, in the final position, the mobile part is positioned so as to bridge the gap between the board and the pin.

Usually, the off-plane cumulated deformations of the pins and the surface may be in the range 0.05 mm to 0.4 mm. Such deformations and thus, the corresponding gaps may be too high to allow soldering of the pin on the surface of the board.

With the invention, in the final, soldering position the mobile part extends from the surface to the solder end of the pin, contacting both (in general). Thus, even if the solder end of the pin and/or the surface are deformed so as to be off-plane with respect to the nominal position where they ought to be positioned, thanks to the invention, the soldering of the pin on the surface can be reliably achieved, the mobile part bridging the gap between surface and pin, thus allowing solder to join the board surface to the pin by capillary action and thus to make electric contact between the surface and the pin.

It should be noted that the gap between the PCB surface and the pin does not necessarily have to be bridged by direct contact between surface and mobile part, or mobile part and pin. The expression ‘the mobile part bridges the gap between the pin and the surface’ must be understood in relation with its desired consequence, ‘to allow soldering of the pin on the surface’. That is, it is not actually necessary that the mobile part directly contacts the surface and the pin. The requirement is that in the soldering position, the mobile part be close enough of the PCB surface, and close enough of the pin, so that solder can fill the surface/mobile part gap and the mobile part/pin gap by capillary action during reflow soldering, whereby a reliable conductive solder joint is formed between the PCB surface and the pin.

In some embodiments, the mobile may protrude ahead of the pin in a soldering direction at the beginning of the reflow soldering stage. This can be achieved, for instance, by using the weight of the mobile part to position it at this stage in the adequate position.

In an embodiment, the movement of said mobile part upon soldering is a translation. In other words, the mobile part and the pin are structured so as to allow the mobile part to slide relative to the pin, when the mobile part abuts the surface of the board. Here, the words ‘upon soldering’ refer to the first stage of the soldering operation, during which the component is brought or moved next to the surface in order to be fastened and soldered thereon.

As an alternative, the movement of the mobile part upon soldering may be a rotation.

The mobile part must generally be mounted loose on the pin, to allow easy movement of the mobile part with respect to the pin. In an embodiment, the mobile part comprises a tubular portion arranged around the pin. The function of this portion is to guide the mobile part so that it moves along the axis of the pin, that is, so that its main movement is mainly a translation along the axial direction of the pin.

When this shape is chosen, the mobile part has a small freedom of movement in the directions perpendicular to the pin axis, and a larger freedom of movement in the axial direction of the pin.

In an embodiment, the mobile part is retained with respect to the pin by retaining means, so as to prevent a movement of the mobile part with respect to the pin in an axial direction of the pin, further than a predetermined position.

Therefore, when the mobile part is so arranged, and when in addition, the mobile part has a tubular portion arranged around the pin, the three degrees of freedom in translation of the mobile part with respect to the pin (that is, relative movements in directions X, Y, Z), are retained or blocked. Usually, they are limited only loosely.

It will be noted that the axial direction of the pin (actually, it is the direction of the solder portion of the pin, which is to be soldered on the board) can make any angle relative to the board. However, two angles are usually preferred:

Most often, in surface mount technology (SMT), the solder portion of the pin extends parallel to the board surface. In this case, if the mobile part has a tubular shape, it moves perpendicular to the axial direction of the pin when it contacts the board surface.

As an alternative option, the end of the pin may abut perpendicularly on the surface of the board. In this case, the mobile part may be formed as a substantially closed shape (like a sock), or as a tube, and moves in the axial direction when it abuts against the surface of the board.

The retaining means which maintain the axial position of the mobile part with respect to the pin may take many forms.

In an embodiment, the retaining means comprise a protrusion, a slot or a notch arranged on the pin or the mobile part. For instance, the mobile part may comprise a protrusion which extends in an elongated slot of the pin. The length and the location of the slot are determined so that when the mobile part moves with respect to the pin so as to reach its final position, wherein it bridges the gap between the board and the pin, the protrusion moves accordingly, but remains within the limits of the slot.

Generally speaking, the position of the pin must be specified so that the mobile part allows soldering of the pin on the surface of the board. However, as mentioned before, the distance between the pin and the surface of the board is subject to variations, mainly due to coplanarity problems of the pins, and/or to PCB warping.

Therefore, the nominal position of the pin must be set so that if the gap between the board surface and the pin (surface/pin gap) is smallest, the mobile part makes the largest possible backward movement; in some embodiments the pin may even directly contact the surface of the board. In this retracted position, the mobile part is often not necessary to bridge the gap between the pin and the board, because the surface/pin gap in soldering position is quite small.

On the other hand, if the surface/pin gap is large, the mobile part is necessary to bridge the gap between surface and pin. In this case, the mobile part makes no or little movement when it abuts the board surface, and remains in the most protruding position. In this position, the mobile part must be positioned and designed so as to allow soldering of the pin by capillary action, capping the distance between the pin and the board surface.

In an embodiment, to allow capillary action and make the soldering easier during paste reflow especially in the last-mentioned case with a large surface/pin gap, the mobile part comprises a slot and/or a hole through which solder can penetrate, to further capillary action of solder and thus help the soldering of the pin. Several holes or holes in the mobile part are also possible.

In an embodiment the pin and the mobile part have the same or compatible plating. This makes the tuning of the soldering easier, and increases solder joint solidity, since the plating of both the pin and the mobile part have the same fusion temperatures.

Another purpose of the present invention to provide a PCB and component assembly, in which the component is reliably soldered on the surface of the PCB, despite variations either in height of the surface of the board due to warping, and/or of the height of the pins (non-coplanarity of pins), in a soldering direction.

In accordance with the present invention, a board and component assembly is provided, which comprises a component as previously defined, said component being soldered on a surface of the PCB.

Preferred embodiments of the invention will now be described by way of example with reference to the accompanying drawings, in which:

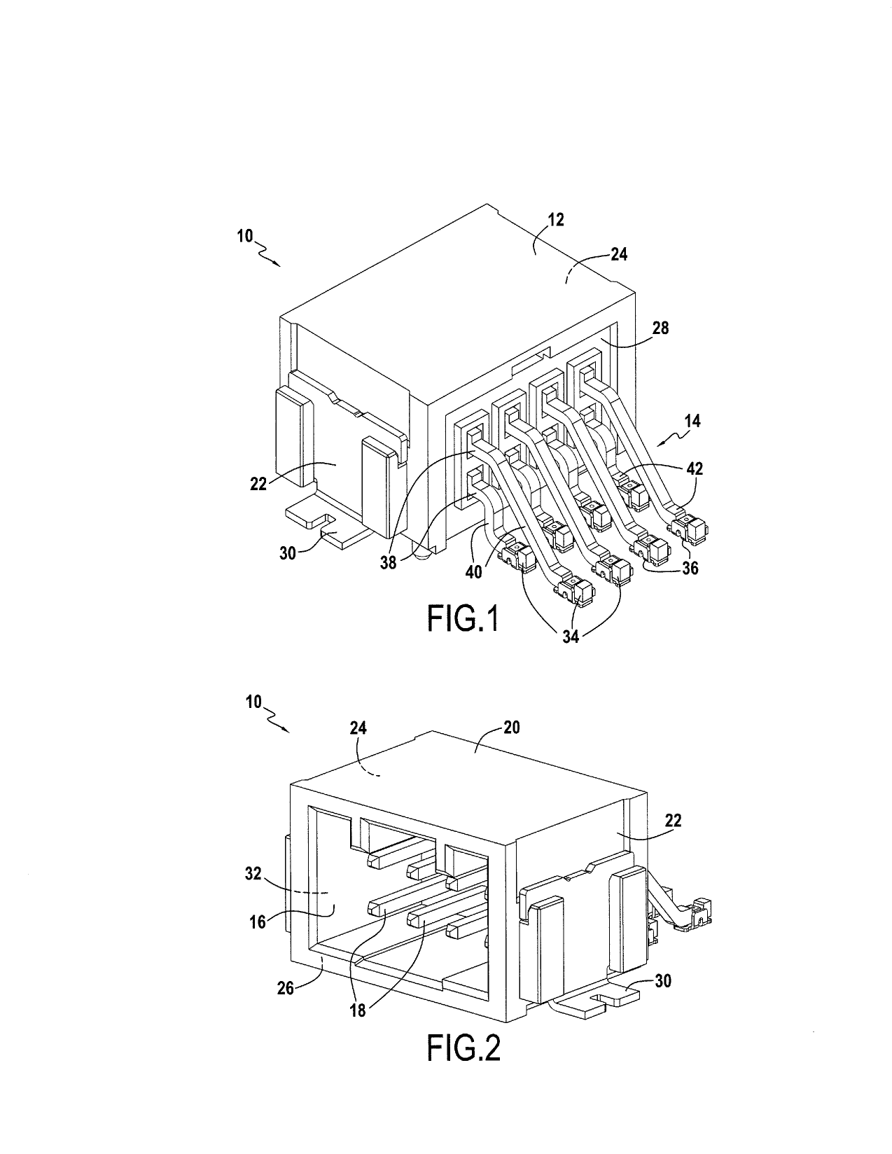

FIG. 1 is a perspective view, on a rear side, of an electrical component to be soldered on a PCB;

FIG. 2 is a perspective view, on a front side, of the electrical component of FIG. 1;

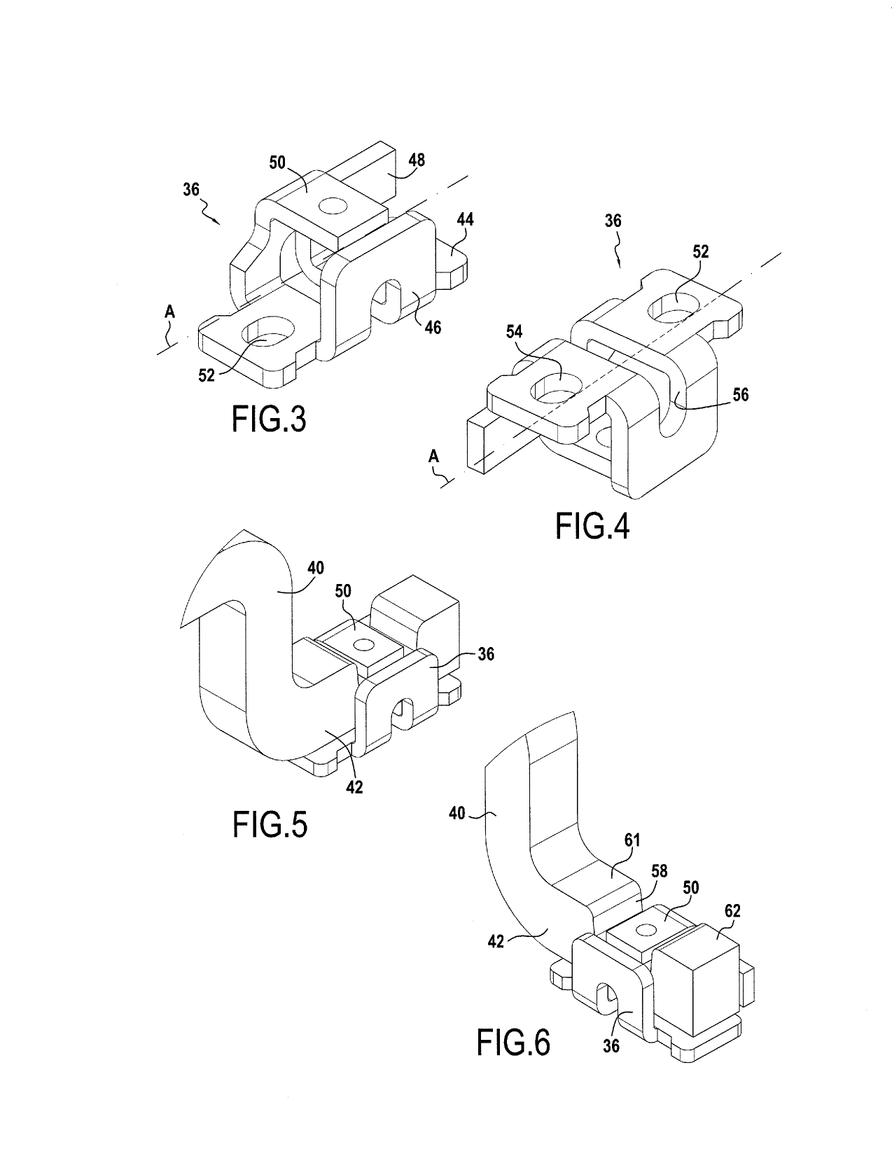

FIGS. 3 and 4 are perspective views of the mobile part used in the component of FIGS. 1 and 2;

FIGS. 5 and 6 are perspective views of the mobile part used in the component of FIGS. 1 and 2, mounted on a pin;

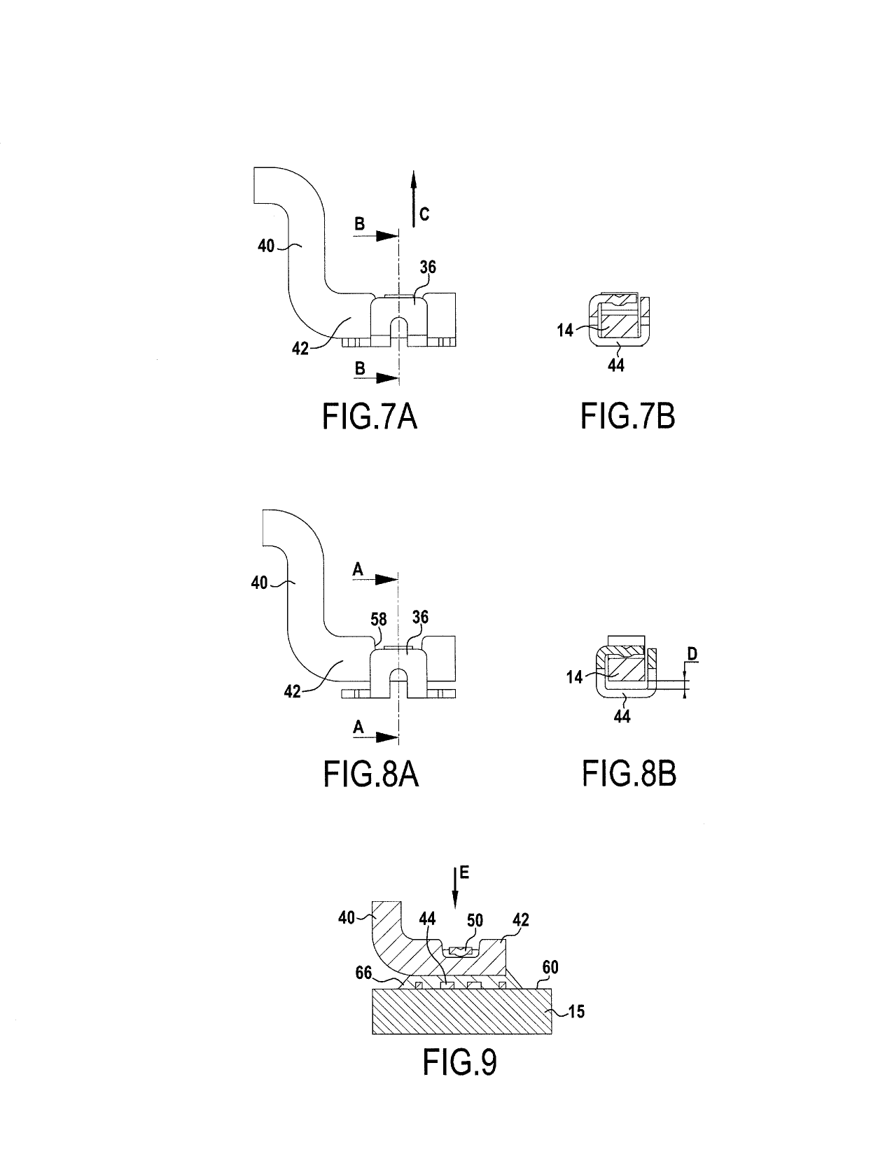

FIGS. 7A-7B, and 8A-8B, are side views and sections of the mobile part of the preceding figures, respectively in uppermost positions (FIGS. 7A-7B) and lowermost positions (FIGS. 8A-8B);

FIG. 9 is an axial cross-section of the mobile part of the preceding figures mounted on a pin, after soldering on the PCB;

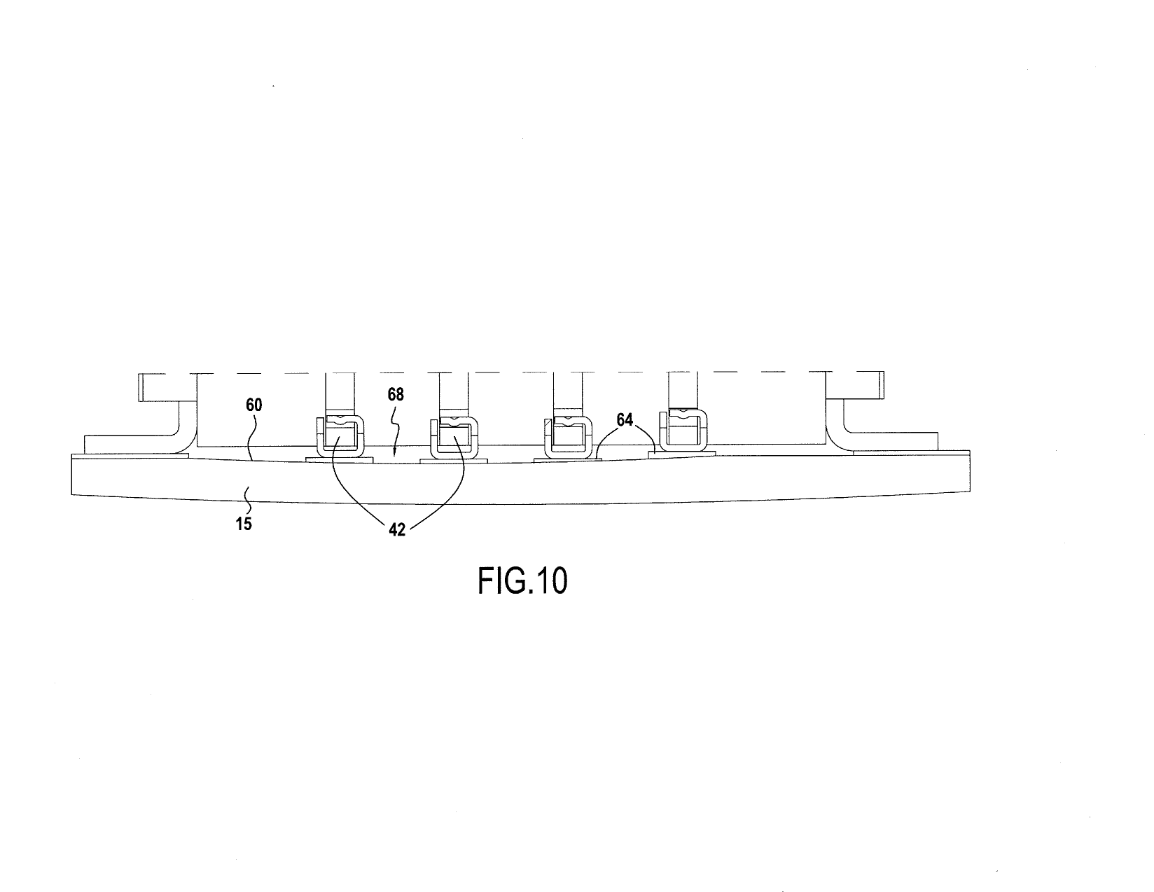

FIG. 10 is a front view of the ends of the pins of the component of FIGS. 1-2, on the PCB, before reflow soldering;

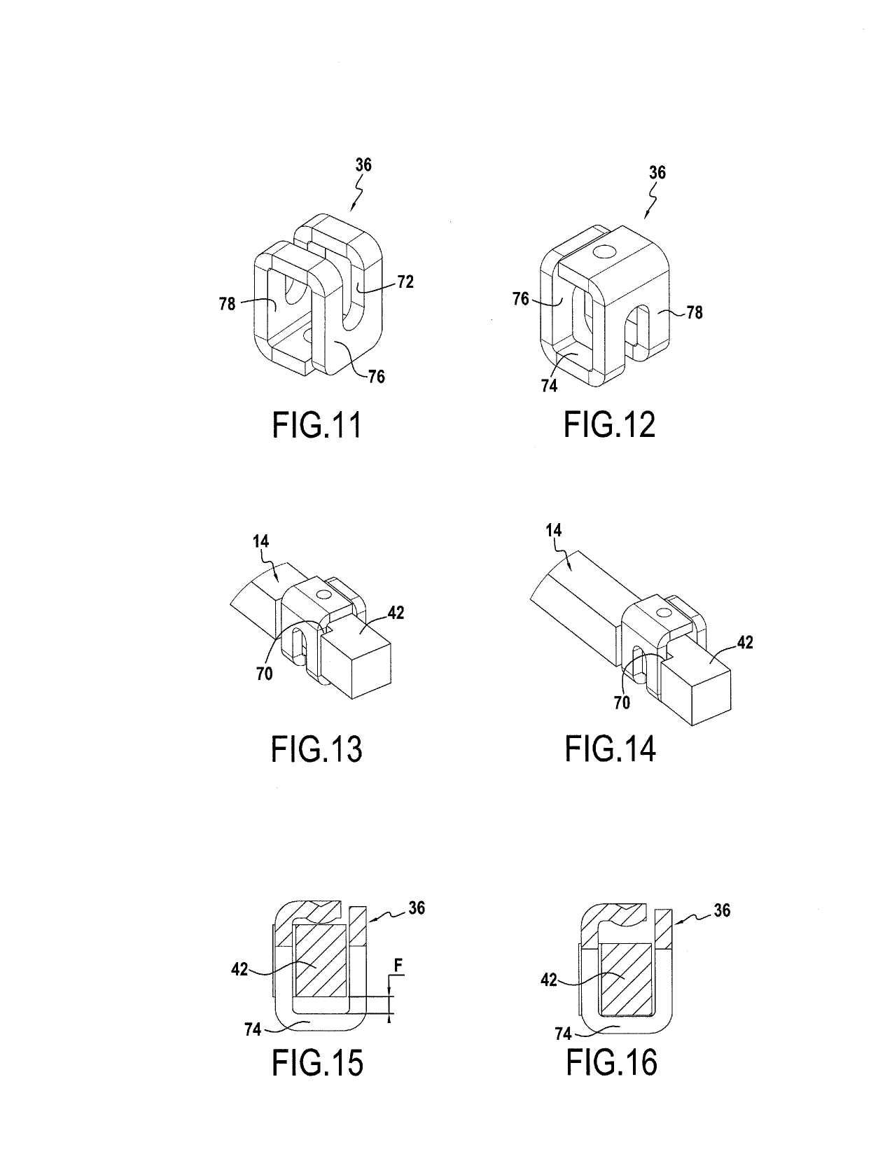

FIGS. 11 and 12 are perspective views of a mobile part adapted to be used in a component in another embodiment of the invention;

FIGS. 13 and 14 are perspective views of the mobile part of FIGS. 11 and 12, mounted on a pin;

FIGS. 15 and 16 are cross-sections of the mobile part of FIGS. 11 and 12, mounted on a pin;

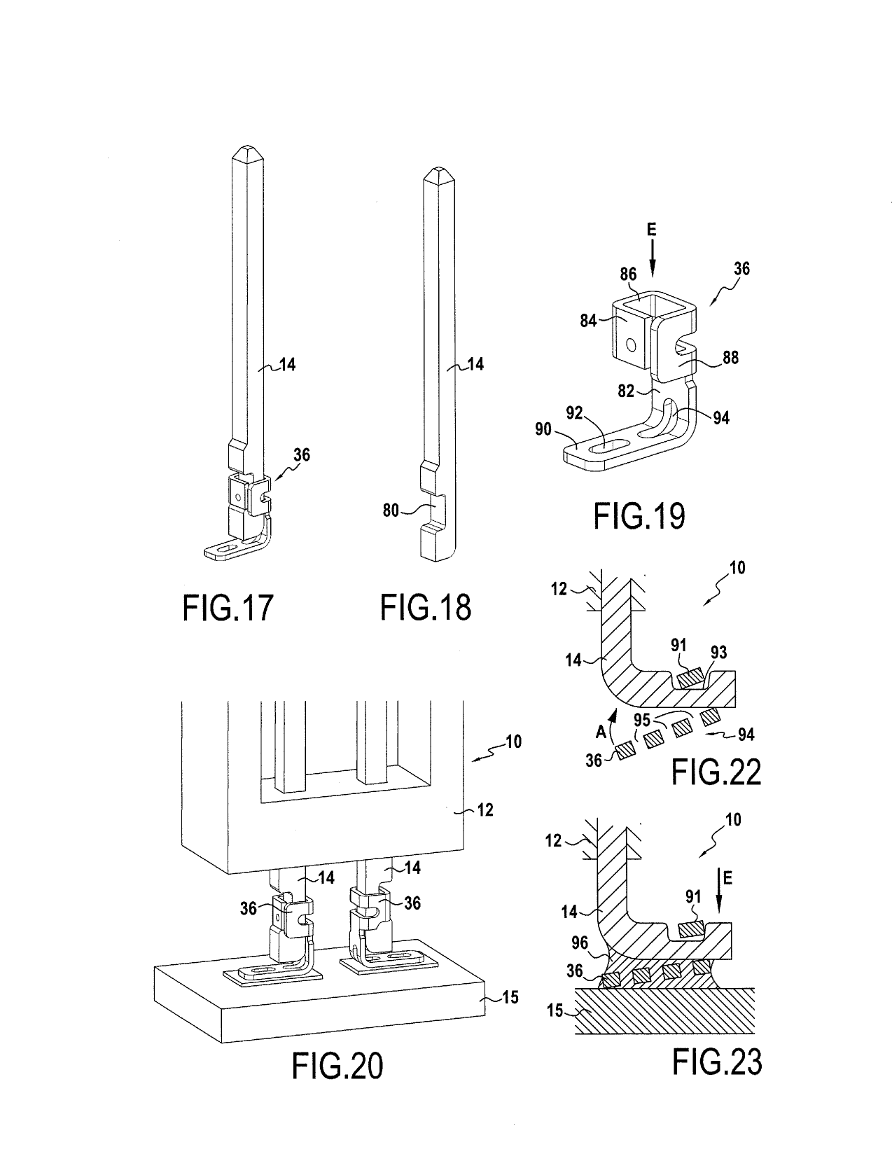

FIGS. 17, 18 and 19 are perspective views showing respectively a pin and mobile part assembly, the pin alone, the mobile part alone, in a third embodiment of the invention;

FIG. 20 is a perspective view showing a board and component assembly, in the third embodiment of the invention;

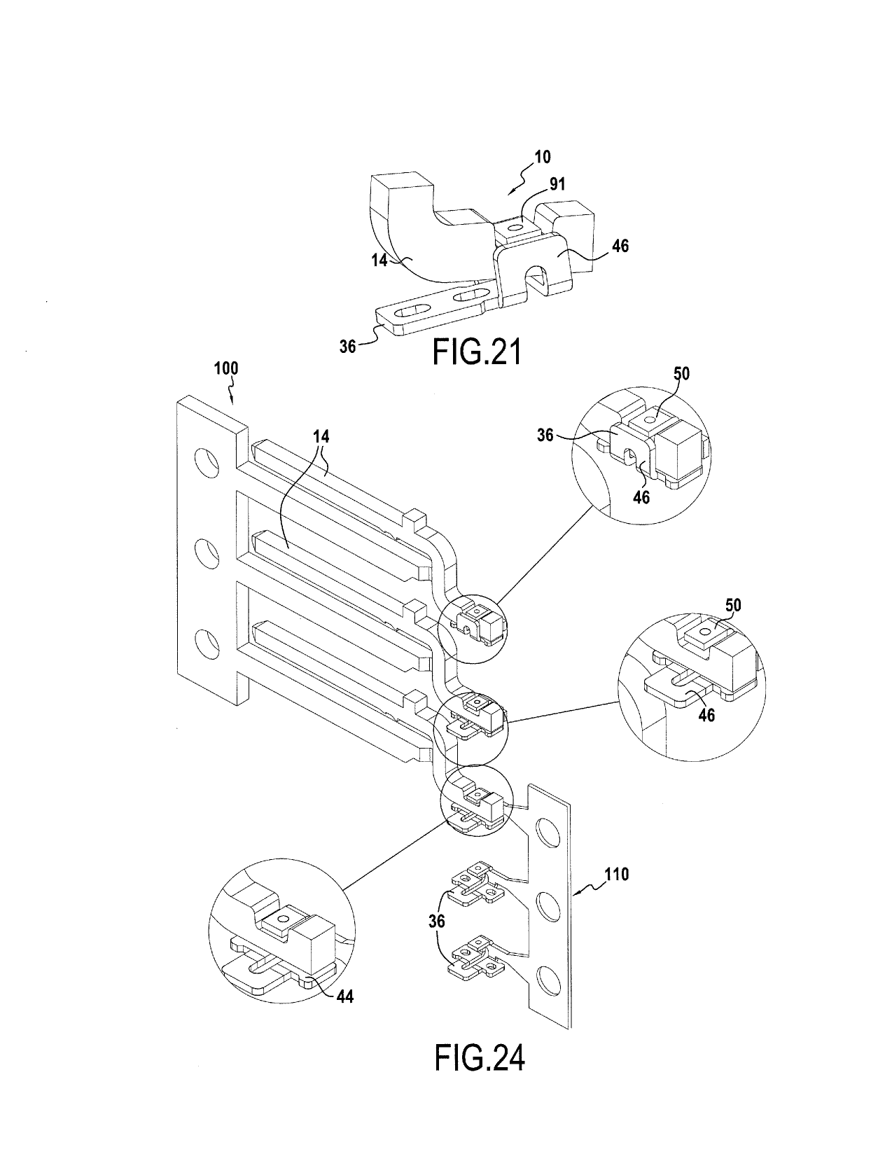

FIG. 21 is a perspective view showing a fourth embodiment of the invention, wherein the mobile part is rotated to reach the soldering position;

FIGS. 22 and 23 are cross-sections presenting a fourth embodiment of the invention; and

FIG. 24 is a perspective view showing the manufacturing and assembling process of pins and mobile parts used in the component of FIGS. 1 and 2.

A first embodiment of the invention appears on FIGS. 1 to 10. In this embodiment, the invention is implemented in an electrical connector. Of course, the invention can also be implemented with any type of electrical component, as long as said component comprises at least one pin that has to be soldered on the surface of a board according to surface mounting technology. For instance, the component might be a second PCB board, to be fastened to the first board and electrically connected to the first board by soldering one or more pins.

In the example of FIGS. 1 and 2, the electrical component 10 is an electrical connector.

It comprises a housing 12, and eight pins 14. The pins 14 are rigidly fixed on the housing 12. Since they are rigidly fixed on the housing 12, pins 14 do not move relative to the housing.

Pins 14 are provided to connect male electrical connector 10 to a not-shown female electrical connector (An embodiment wherein connector 10 would be a female connector could also have been chosen to present the invention). In this purpose, the housing 12 is hollow and comprises an inner chamber 16 in which male portions 18 of pins 14 extend in parallel. The female connector can be inserted inside chamber 16, so that female terminals contact respectively the pins 14 to make electrical connections with them.

The housing 12 has a general parallelipipedic shape with a top face 20, side faces 22 and 24, a bottom face 26, a rear face 28 (the front face is open). Housing 12 is a plastic moulded part and is thus electrically insulating.

The housing 12 is to be fastened on the planar surface 60 of a board 15 (FIG. 10), in particular a PCB. In this purpose, face 26 is flat so as to be adapted to lie directly on said surface.

In this embodiment as well as in the next embodiment, for sake of simplicity the surface of the PCB is assumed to extend horizontally.

To fasten housing 12 on the PCB, two solder metal pegs 30 and 32 are provided next to side surfaces 22 and 24. The solder pegs 30 and 32 are arranged so as to extend just above the surface of the PCB, to allow their easy soldering on board 15.

The electrical connection of the connector 10 to the PCB is realized by reflow soldering each of the pins 14 to corresponding pads provided on the surface of the PCB.

In theory, all pins 14 are supposed to be coplanar, and the surface of the PCB is also supposed to be a perfect plane. When this is realized, soldering pins 14 is an easy operation.

However, practically the PCB surface may be warped, or pins 14 may not be coplanar due to tolerances of connector manufacturing, whereby the solder ends 34 of pins 14 may not be coplanar with the plane of surface 60.

To permit the solder ends 34 to be reliably soldered onto the PCB, even if such lack of coplanarity arises, each of the pins 14 is equipped with a mobile part 36.

Mobile part 36 is made of a conductive material and is adapted to withstand soldering operations, in particular a reflow step. It is usually made of the same metal as pin 14, and if possible has the same plating.

In preamble, some information must be given about the shape of the pins 14. Pins 14 are formed in metal sheet by stamping, cutting and bending. From the front part to the rear part of connector 10, each pin 14 comprises a male portion 18 which extends inside housing 12, parallel to surface 60, an enlarged portion 38 to maintain pin 14 as it passes through the wall of housing 12, and then, outside and to the back of the housing 12, a short straight portion 38 extending parallel to the surface of the PCB, a sloped portion 40, and another straight portion 42 extending parallel to the surface of the PCB.

Pins 14 are arranged in two groups, because male parts 18 are disposed in chamber 16 at two different heights to form two rows of terminals. Accordingly, the rear portions of pins 14 (in particular the sloped portions 40) have two different shapes. However, all pins 14 have the above-mentioned structure.

The shape of mobile parts 36 is illustrated in particular by FIGS. 3-6. Parts 36 are also made by stamping, bending and cutting.

Parts 36, as well as pins 14, are subjected to plating to prevent them from corrosion and permit them to be soldered on board 15.

Each part 36 is designed to be placed around the straight portion 42 of pins 14 and therefore, generally speaking, presents a tubular shape. Since the section of the pins 14 is rectangular, the general tubular shape has a substantially rectangular section, defining in part 36 a bottom portion 44, two side portions 46 and 48, a top portion 50.

The mobile part 36 is loosely mounted (or has clearance) with respect to the pin in the three directions. Therefore, part 36 may move freely—in certain limits—relative to pin 14 when it is mounted thereon.

Two holes 52, 54 are formed on the bottom portion 44; and a slot 56 is formed through the bottom portion 44 and the side portions 46 and 48. Thanks to holes 52, 54, and slot 56, the solder may flow easily through part 36 during reflow soldering by capillary action, whereby reliable soldering is achieved. In particular, the bottom portion 44 has a flat shape and extends on a wide surface, larger than the other portions of part 36 (when seen in top view), in order to have a large contact surface with the points of surface 60 where pin 14 is to be soldered. This large contact surface in conjunction with the holes 52, 54 and the slot 56 furthers the capillary action.

Of course, the means to facilitate capillary action and movement of the solder during reflow soldering can take any shape other than holes and/or slots, and adapted to enable the solder to flow from the board surface towards the pin.

In FIGS. 5 and 6, part 36 is illustrated mounted on the portion 42 of a pin 14. As shown on these figures, in order to constrain the mobile part 36 to remain in a given axial range, with respect to straight portion 42, the straight portion 42 presents a notch 58. Said notch 58 is formed on a top surface of a portion of the straight portion 42, and locally reduces the height or thickness of the pin 14.

The flat top portion 50 of part 36 is folded so as to extend through the notch 58; it is barred from moving in the axial direction outside of notch 58 by the two outer parts 61 and 62 of the straight portion 42, which are located on both sides of notch 58. Accordingly, notch 58 in conjunction with top portion 50 forms retaining means, which prevent a movement of the part 36 with respect to the pin 14 in an axial direction of the pin further than a predetermined position or range (the range of the notch 58).

The different positions that may be taken by part 36 along the soldering direction, relative to the pin 14 and the board surface 60 are illustrated by FIGS. 7A to 10.

FIGS. 7A, 7B show part 36 in its uppermost position, the top direction being represented by arrow C (The top direction is opposite to the soldering direction, shown by arrow E on FIG. 9). Conversely, FIGS. 8A, 8B show part 36 in its lowermost position.

As shown on FIG. 8B, in the lowermost position of part 36, a gap D is formed between the bottom portion 44 of part 36 and the bottom of pin 14. As shown on FIG. 7B, in the uppermost position of part 36, gap D has been reduced to zero, due to part 36 having moved upward of a distance D.

This can be understood from FIGS. 9 and 10, and bearing in mind the steps of the soldering process.

In the soldering process, firstly pads 64 (FIG. 10) of solder paste are formed on surface 60 at locations where pins 14 are to be soldered.

Then, the connector 10 is moved towards its fastening position, in direction E which is the soldering direction, perpendicular to the board surface.

Because of their weight, parts 36 at this stage are in their lowermost position relative to pins 14, shown on FIG. 8B. Therefore, parts 36 protrude from pins 14 in the soldering direction and contact or abut against surface 60 before pins 14 in order to compensate the PCB warp and/or the non-coplanarity of pins.

This contact takes place usually a bit before connector 10 has reached its final position; usually, connector 10 further moves a little bit in the soldering direction E until it reaches its final position.

During this last movement, parts 36 are pushed upward (relative to pins 14) a little bit to take a final, soldering position between the uppermost and the lowermost positions.

Then, the soldering step takes place by placing the board inside an oven where temperature is increased to soldering temperature. The solder paste melts and by capillary action, flows upward (to a limited extent) along the walls of parts 36 and pins 14. This allows pins 14 to be soldered onto the surface 60, as shown by FIG. 9 where solder is represented by reference 66.

As shown by FIG. 10, thanks to parts 36, a lack of co-planarity of board 15, for instance, can be compensated. Indeed, even if pins 14 and more precisely end straight portions 42 thereof are located at constant heights, whilst the board 15 presents a slight depression 68 (which causes pads 64 to be positioned at different heights), all portions 42 can be reliably soldered onto all pads 64, because the mobile parts 36, by bridging the gap between the lower parts of pins 14 (portions 42) and the surface 60 of board 15, allow the solder by capillary action to connect pins 14 to board 15.

Another embodiment of the invention is presented in relation with FIGS. 11 to 16. For sake of simplicity, for all embodiments of the invention, elements having substantially the same shape and/or function as in the first embodiment bear the same reference sign as in the first embodiment.

In this embodiment, the mobile part 36 presents a tubular shape. Part 36 is disposed around the solder end of a pin 14. This part of pin 14 is formed as a straight portion 42 and presents a lateral notch 70. This notch 70, in which a side wall 78 of part 36 is blocked, acts as retaining means to prevent unwanted movements of part 36 in the axial direction of straight portion 42.

In order to facilitate the upward movement of melted solder during reflow soldering, so that pin 14 be soldered to surface 60, part 36 comprises a slot 72 formed through its bottom portion 74 and part of its side walls 76, 78.

As shown on FIGS. 14 and 16, part 36 in this embodiment as in the first embodiment, is free—before soldering—to move vertically (the soldering direction is the vertical direction), ie perpendicularly to the axis of the straight portion 42 of pin 14. It can move between a lowermost position (FIG. 14), and an uppermost position (FIG. 16). In the lowermost position, a gap F is formed between the bottom portion 74 of part 36, and the bottom of straight portion 42.

When connector 10 is placed on the PCB, in order to solder pin 14 on surface 60, part 36 contacts surface 60 and moves upward to a position between the uppermost and the lowermost positions. When soldering takes place (upon heating of the board and component assembly), solder flows and fills the gaps between board 60 and part 36, and between part 36 and pin 14 respectively, in the same manner as in the first embodiment.

A third embodiment of the invention is presented on FIGS. 17 to 20. In this embodiment, a component 10 comprising a housing 12 and a pin 14 is fastened and soldered on a board 15.

The main difference which distinguishes this embodiment from the previous ones, in that the solder end of pin 14, in this embodiment, extends in the soldering direction E in direction of the board 15 (rather than be parallel to the surface of board 15).

In this embodiment, like in the previous ones, the mobile part 36 comprises a tubular portion placed around the solder end portion of pin 14. Since the section of pin 14 is rectangular, the tubular portion has a substantially rectangular section, defining four side walls 82, 84, 86 and 88. Side wall 84 is trapped in a notch 80 of pin 14, which thus retains part 36 and limits its movements in the soldering direction (here, the axial direction of pin 14), with respect to pin 14.

The side wall 82 extends further than the end of pin 14 and thus protrudes ahead of pin 14 in the soldering direction. The end part 90 of side wall 82 is bent perpendicularly with respect to the main part of side wall 82. Therefore, this end part 90 extends perpendicularly to the soldering direction and thus, is parallel to the surface of board 15 when component 10 is soldered on board 15.

When the fastening and the soldering of component 10 on board 15 begin, component 10 is brought next to board 15 and put in its final position with respect to board 15. It is fastened by not shown fastening means to board 15.

During this movement, end part 90 abuts against board 15 and moves relative to pin 14 in the direction opposite to the soldering direction E, until it reaches its final position. In this position, part 36 bridges the gap between board 15 and the solder end of pin 14.

Then during reflow, solder flows upward (in the direction opposite to the soldering direction E) along part 36, in particular through two holes 92 and 94 formed into end part 90. Holes 92 and 94 help solder to flow upward and thus permit a reliable soldering of pin 14 on board 15.

FIGS. 21 to 23 present a fourth embodiment of the invention. In this embodiment, a mobile part 36 is rotatably mounted on the solder end of a pin 14. On the position presented on FIGS. 21 and 22, part 36 is in slantwise configuration with respect to the solder end of pin 14.

To allow rotation of part 36 with respect to pin 14, part 36 comprises a fulcrum 91 which is positioned in a notch 93 of pin 14. Before soldering, part 36 may thus rotate freely (in a predetermined, limited angular range) around fulcrum 91, with respect to a rotation axis perpendicular to the axis of pin 14 (arrow A).

When the reflow soldering of component 10 on board 15 takes place (FIGS. 21, 22), the solder end of pin 14 is moved next to the surface of board 15.

When part 36 abuts against board 15, it rotates around fulcrum 91. This rotation may be accompanied by a slight translation. This movement causes the lower portion 94 of part 36, i.e., the portion located on the side of board 15 relative to pin 14, to move closer to pin 14, which then allows a further movement of pin 14 towards board 15, in the soldering direction E. At the same time, solder paste flows upward and through the holes of part 36, in order to achieve connection between surface 60 and pin 14.

FIG. 23 represents pin 14 once soldered on board 15, after reflow. Solder 96 has flown upward through holes 95 formed in the lower portion 94, and joins board 15 to pin 14, thus making a reliable electric contact between board 15 and pin 14.

FIG. 24 presents a part of the manufacturing process of pins 14 and mobile parts 36. As briefly mentioned before, pins 14 and mobile parts 36 are formed continuously in a progressive die by stamping, bending and cutting in a well-known manner.

After these first operations, a first band 100 of pins 14 and a second band 110 of mobile parts 36 are formed. Both bands are then placed in a not-shown common progressive die, in which each pin 14 is positioned next to a mobile part 36.

At this stage, mobile parts 36 don't have yet a tubular shape: Their three walls 44, 48 and 50 have been folded at right angles so as to fit with the three sides of the straight portions 42 of the pins 14, but the sides 46 have not yet been folded.

For this reason, the straight ends 42 of pins 14 can be introduced between the three walls 44, 48 and 50 of mobile parts 36.

The enlarged details of FIG. 24 show in particular the step during which the sides 46 are folded on the solder end of pins 14. By this folding, the mobile parts 36 are fixed, after being cut off from band 110, onto the solder end of pins 14.

There remain not-shown cutting operations, during which pins 14 are cut off from band 100, before being fitted into the housing 12.

Lastly, the pins 14 equipped with mobile parts 36, are fixed on housings 12 in a well-known manner. This completes the making of connectors 10.

Advantageously, the mobiles parts 36 are fitted on pins 14 before fastening of the pins 14 on housings 12, whereby no mounting operation of the mobile parts during of after the fastening of pins 14 on the housings 12 is necessary.

1. Electrical component, comprising at least one pin to be soldered on a PCB surface using Surface Mount Technology (SMT), wherein a mobile part is movably mounted on the pin, and in that the mobile part is adapted, when the component is brought next to said surface in order to be soldered thereon, to abut against said surface and to move with respect to said pin, so as to adopt a position wherein it bridges a gap between the pin and the surface to allow soldering of the pin on the surface.

2. Electrical component according to claim 1, wherein said movement of said mobile part upon soldering is a translation.

3. Electrical component according to claim 1, wherein said movement of said mobile part upon soldering is a rotation.

4. Electrical component according to claim 1, wherein the mobile part comprises a tubular portion arranged around the pin.

5. Electrical component according to claim 1, wherein the mobile part is retained with respect to the pin by retaining means, so as to prevent a movement of the mobile part with respect to the pin in an axial direction of the pin further than a predetermined position.

6. Electrical component according to claim 5, wherein the retaining means comprise a protrusion, a slot or a notch arranged on the pin or the mobile part.

7. Electrical component according to claim 1, wherein said component comprises a housing, and said pin is rigidly fixed on said housing.

8. Electrical component according to claim 1, wherein the mobile part comprises a slot and/or a hole through which solder can penetrate, to help the soldering of the pin by capillary action.

9. Electrical component according to claim 1, wherein the pin and the mobile part have the same or compatible plating.

10. Electrical component according to claim 1, wherein the component is an electrical connector.

11. Electrical component according to claim 1, wherein the mobile part is loosely mounted with respect to the pin.

12. PCB and component assembly, comprising a component according to claim 1, said component being soldered on a surface of said PCB.
